(19) United States
(12) Patent Application Publication
(10) Pub. No.: US 2013/0319718 A1
(43) Pub. Date: Dec. 5, 2013

(54) Sturdy Flexible Cover For A Light Switch "Compact Switch Guard"

(71) Applicant: Saundra Elaine Woods, Piscataway, NJ (US)

(72) Inventor: Saundra Elaine Woods, Piscataway, NJ (US)

(21) Appl. No.: 13/486,022

(22) Filed: Jun. 1, 2012

(51) Int. Cl. H05K 5/03

(52) U.S. Cl. 174/66

(57) ABSTRACT

A flat sturdy flexible plastic cover for the light switch which have four rounded corners 2 so that it can be removed and replaced if need be without causing harm to the individual that is handling the compact switch guard, the center of the compact switch guard has a half of a bubble 8 in the center that covers the light switch, each compact switch guard have adhesive 10 on the back so that it will hold firmly over the light switch in the desired position off or on.

### CROSS-REFERENCE TO RELATED APPLICATIONS

This application claims the benefit of provisional patent application Ser. No. 61/491/357, filed 2011 May 31 by the present inventor.

### FEDERALLY SPONSORED RESEARCH

Not Applicable

### SEQUENCE LISTING OR PROGRAM

Not Applicable

### BACKGROUND OF THE INVENTION

1. Field of Invention

This invention relates to sturdy flexible plastic cover for light switch, specifically to hold the light switch in a off or on position.

2. Prior Art

Hardware stores supply consumers with several different types of light guards that keep the light switch in a position, either on or off depending on the inventor. Initially the switch guard cover was mounted in by screws under the light plate to hold the device in position, which gave it an unappealing appearance.

3. Objects and Advantages

Several objects and advantages of the steady flexible plastic cover for the light switch, which is the present invention, are:
(a) To provide a compact switch guard which can be produced in variety of colors for the convenience of the customer?
(b) To provide an attractive appearance to the exterior wall which has the light switch and giving the customer an option now?
(c) To provide a solution for light switches that has more than one appliance on the breaker and is an important device if turned off.
(d) To provide a solution for the light switch that needs to stay on for safety purpose.
(e) To provide a compact switch guard that can be easily remove if desired.
(f) To provide flexibility to the movement of the product
(g) To provide a solution to a problem which almost every household have experienced by place tap over there light switch to provide security so that it will not be disabled.

### SUMMARY

In accordance with the present invention the sturdy flexible plastic cover for a light switch the compact switch guard, comprises a flat body having a estimate size of 2½ inch in length and 1½ inch in width, the center is a estimated size of 1 inch in length and ⅛ inch width and shaped like a half of a bubble which covers the light switch completely holding it firm in position. The half of bubble is made with a growth scale of 1 inch which fit firmly against the light switch as one piece stopping it from moving, the back of the switch guard has sticky adhesive on it so that it hold firmly over the light switch. I am well aware of the problem that individuals have as well as myself with having to many appliances on one breaker and having to tape the light switch so that no one can hit the switch by a mistake, this a very common situation among most household and friends and family that I picked my idea to are waiting for there compact switch guard this invention may not be the best idea but is it needed right now in my house and your house as well.

### DRAWINGS—FIGURES

FIG. 1 Show several aspects of the compact switch guard supplied with four round edged corners, with a half bubble shape off the base at 1 inch length covering the light switch.

FIG. 2 Shows the compact switch guard in reverse with the back showing the location of the adhesive and the shape of the hole where the light switch is placed.

### DRAWING—REFERENCE NUMERALS

2 Round Corners

3 Base

6 Center of Base

8 ½ inch Bubble

10 Adhesive Dark Lines

12 Hole of ½ inch Bubble

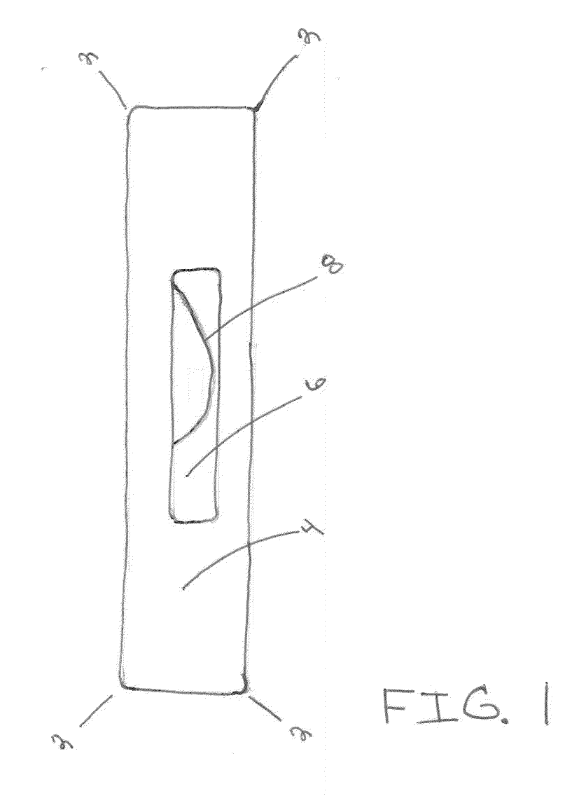

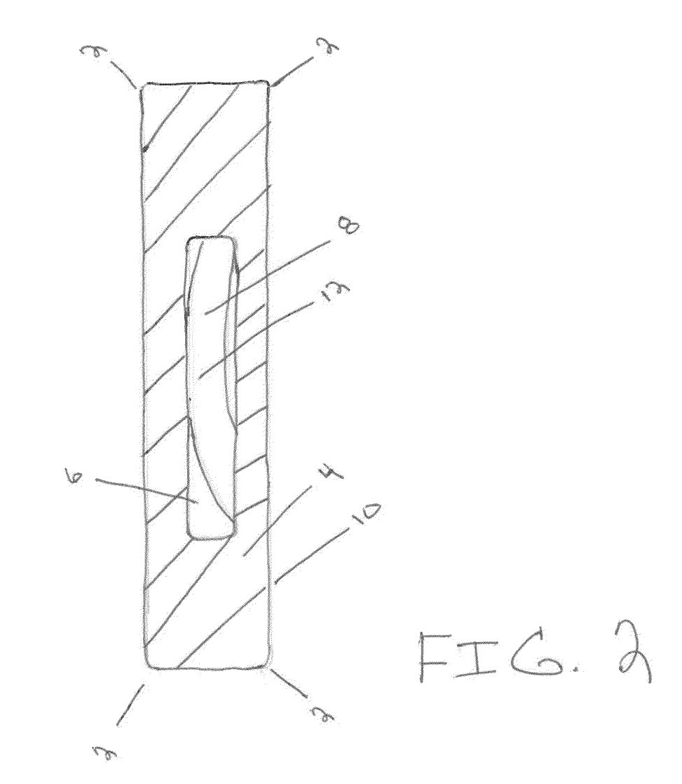

### DETAILED DESCRIPTION—FIGS. 1 AND 2 PREFERRED EMBODIMENT

A preferred embodiment of the compact switch guard of the invention is illustrated in FIG. 1 and FIG. 2 the compact switch guard has four rounded edged corners 2 on a long and a hole in the center 12 for the ½ inch half bubble 8 shaped cover to be placed in order for the light switch to be place firmly in place be the adhesive 10.

### Claim

An object that is placed over a light switch that holds the device in place.

1. I claim in the compact switch guard the type comprising flat body of sturdy flexible plastic which has four rounded corners, that has a half shaped bubble in the center that cover the light switch completely holding if firm while the adhesive secure it in place.

2. I claim the compact switch guard of claim I wherein said the body of material composed of chemicals which construct sturdy flexible plastic.

3. I claim the size of the compact switch guard would be 2½ inch in length and 1½ inch in width.

4. I claim the compact switch guard is secured by adhesive of any kind with strength.

5. I claim wherein that the base and or body is made of sturdy flexible plastic

6. I claim wherein that the compact switch guard can be product in a several different colors.
